(19) United States
(12) Patent Application Publication
(10) Pub. No.: US 2023/0403827 A1
(43) Pub. Date: Dec. 14, 2023

(54) THERMAL CONTACT APPARATUS

(71) Applicant: RAFAEL ADVANCED DEFENSE SYSTEMS LTD., Haifa (IL)

(72) Inventor: Alon TAL, Natur (IL)

(21) Appl. No.: 18/250,146

(22) PCT Filed: Oct. 20, 2021
(86) PCT No.: PCT/IL2021/051246

§ 371 Date: Apr. 21, 2023

(30) Foreign Application Priority Data
Oct. 21, 2020 (IL) 278203

(51) Int. Cl. H05K 7/20

(52) U.S. Cl. CPC H05K 7/20454

(57) ABSTRACT

The invention relates to a thermal contact apparatus, comprising: a first plate, suitable to be connected to a heat source, absorb heat from said heat source, and transfer the heat to other components of the apparatus; a first set of fibers, suitable to absorb heat from said first plate and transfer the heat to other components of the apparatus, wherein said first set of fibers is connected to said first plate; a second set of fibers, suitable to absorb heat from said first set of fibers and thansfer the heat to other components of the apparatus, wherein said first and second sets of fibers are in contact; and a second plate, suitable to absorb heat from said second set of fibers and transfer the heat out of the apparatus, wherein said second set of fibers is connected to said second plate.

### FIELD OF THE INVENTION

The present invention relates to the field of heat transfer devices. More particularly, the invention relates to an apparatus that allows efficient heat transfer from a heat source.

### BACKGROUND OF THE INVENTION

Heat transfer is a broad field in thermal engineering, relating among the rest to the conversion and exchange of thermal energy, which is in fact heat energy, between physical elements. There are several ways to perform heat transfer—thermal conduction, thermal convection, thermal radiation, and transfer of thermal energy by phase changes. The present invention relates to thermal contact between two bodies.

Heat transfer occurs when two elements (or one element in relation to its environment) are at different temperatures and are in contact with each other. At such a condition, heat flows from the hotter element (or environment) to the other. The heat transfer will continue until the elements reach a thermal equilibrium—as long as there is a temperature difference. Heat convection occurs when a flow of fluid, which can be gas or liquid, transfers heat along with the flow. The convection can be natural or forced (for example, by a ventilator). Heat transfer in a convection process is also partially influenced by diffusion as well.

The contact of two elements that will undergo an efficient heat transfer process requires mechanical adjustments, such as mounting constraints and production with tight tolerances, and also the use of materials suitable for the operational temperature rage and mechanical pressure. A rigid interface provides a sufficient transfer of dynamic mechanical stresses and constraints between the participating elements. Efficient heat transfer between two parts (with low thermal resistance contact), requires high quality matching surfaces. Pressing one surface against the other would improve thermal contact.

A common disadvantage of the heat transfer devices known in the prior art is the fact that when using an array of mechanical components, they can be sensitive to movements/vibrations produced in the system they are attached to, and quite a few systems that require heat elimination produce frequent vibrations. Rigid mechanical contact between a device and a heatsink apparatus, which is suitable for efficient heat transfer, might be problematic in case of shocks and vibration in sensitive devices

It should be noted that the phrase “thermal contact apparatus” describes an apparatus suitable to be attached to another body (apparatus, device, element, system etc.) and provide heat elimination from said body while in contact.

It is therefore an objective of the present invention to provide a thermal contact apparatus and method that enable efficient heat transfer for heat elimination from heat-generating devices.

It is another objective of the invention to provide a thermal contact apparatus and method, wherein said apparatus is suitable to be connected to vibrating and/or moving devices while enduring such vibrations and/or movements without suffering from a mechanical or other type of damage.

It is yet another objective of the present invention to provide a thermal contact apparatus with high tolerance in order to avoid the transfer of movements and/or vibrations from the body it is attached to toward other components. The other components refer to different parts of the thermal contact apparatus itself and/or to other components that are attached to said apparatus.

Other objectives and advantages of the invention will become apparent as the description proceeds.

### SUMMARY OF THE INVENTION

The present invention relates to a thermal contact apparatus, comprising:
a) a first plate, suitable to be connected to a heat source, absorb heat from said heat source, and transfer the heat to other components of the apparatus;
b) a first set of fibers, suitable to absorb heat from said first plate and transfer the heat to other components of the apparatus, wherein said first set of fibers is connected to said first plate;
c) a second set of fibers, suitable to absorb heat from said first set of fibers and thansfer the heat to other components of the apparatus, wherein said first and second sets of fibers are in contact; and
d) a second plate, suitable to absorb heat from said second set of fibers and transfer the heat out of the apparatus, wherein said second set of fibers is connected to said second plate.

According to one embodiment of the invention, the first and/or second set of fibers comprise fiber-bundles. Whether the sets of fibers comprise single fibers or fiber-bundles, the fibers of the first set are suitable interweave with the fibers of the second set.

According to another embodiment of the invention, the first and/or second plate further comprises cavities, and the first and/or second sets of fibers are connected to corresponding plates by the insertion of said sets of fibers into said cavities. According to another embodiment of the invention, the first plate is an integral part of a heat source, or its casing. The phrase “heat source” refers to any element that requires heat elimination, including heat-generating devices. According to some embodiments the first and/or second plate further comprises a heatsink structure, for instance, a structure of fins and ducts.

The apparatus of the present invention is not restricted to any specific materials. That said, an exemplary material for the plates is aluminum, and an exemplary material for the fibers is cooper. Of course, many other materials can be used for manufacturing the apparatus of the present invention, as obvious to a person skilled in the art.

According to another embodiment of the invention, the apparatus further comprises a filling material, suitable to be positioned inside the cavities of the plates. Such filling material can be used in order to provide an improved thermal conductivity between the fibers and the plates. According to yet another embodiment of the invention, the apparatus further comprises an intermediate material, suitable to be positioned between the fibers and improve the thermal conductivity between them.

The invention also relates to a method for heat elimination from a heat source, comprising:
a) attaching a first plate to a first set of fibers, wherein said first set of fibers is suitable to absorb heat from said first plate and transfer the heat to other components;
b) attaching said heat source to said first plate, wherein said first plate is suitable to absorb heat from said heat source and transfer the heat to other components;
c) attaching a second set of fibers to a second plate, wherein said second plate is suitable to absorb heat from said second set of fibers and transfer the heat to the environment; and
d) positioning said first set of fibers in relation to a second set of fibers so that said first and second sets of fibers are in contact, thus allowing said second set of fibers to absorb heat from said first set of fibers and thansfer the heat to other components.

According to one embodiment of the invention, the method for heat elimination further comprises creating cavities in first and/or second plates, and according to another embodiment, further comprises the insertion of first and/or second sets of fibers into the cavities of corresponding plates.

According to another embodiment of the invention, the method for heat elimination further comprises filling the cavities of the first and/or second plates with a filling material. According to yet another embodiment of the invention, the method for heat elimination further comprises providing an intermediate material, suitable to be located between fibers of the apparatus.

### BRIEF DESCRIPTION OF THE DRAWINGS

FIG. 1A is a front view of a thermal contact apparatus, according to one embodiment of the present invention;

FIG. 1B is an enlarged view of section A of FIG. 1A, showing the hot and cold fibers interweaved with one another, and the heat transference through them;

FIG. 2 is a perspective view of a thermal contact apparatus, according to another embodiment of the present invention;

FIG. 3A is a perspective side view of the thermal contact apparatus of FIG. 2;

FIG. 3B is a sectional view of section B-B of FIG. 3A;

FIG. 4 is a cross-sectional view of the apparatus of FIG. 2, wherein the section was performed parallel to the length of the bundles, and wherein all bundles, except from two bundles shown in the figure (one on each plate), were removed in order to comfortably illustrate the cavities of the apparatus and the integration between the two remaining bundles. It also shows that the fibers of the bundles are interweaved with one another, and the cavities in the plates;

FIG. 5A shows another exemplary illustration of a possible use of the thermal contact apparatus, according to another embodiment of the invention. This figure shows an electronics case, a cover, and a plate. This figure also shows that the cover is provided with a heat sink that comprises fins and ducts;

FIG. 5B shows another exemplary illustration of a possible use of a thermal contact apparatus. In this figure, an Inertial Navigation System (INS) is connected to a plate via shock absorbers, wherein the hot fiber-bundles are connected to the bottom surface of the INS, and the cold fiber-bundles are connected to the plate;

FIG. 6 shows a schematic illustration of an experiment that included a serial structure installation, which is a double-sided apparatus, wherein two thermal contact apparatus were provided, one on each side of a heating sticker;

FIG. 7A is a cross-sectional view, wherein the section was performed in parallel to the length of the fibers, in order to show that the fiber-bundle is positioned inside the cavity of the plate, and that during the manufacturing process a pin pushes the fibers of the bundle into the cavity;

FIG. 7B shows the bundle of FIG. 7A inside the cavity after the manufacturing process and after the pin was removed;

FIG. 7C shows the bundle of FIG. 7A in the same sectional view as in FIGS. 7A and 7B, after the fibers of the bundle are aligned;

FIG. 8A shows an illustration of a square-shaped bundle inside a plate, wherein only the part of the bundle that is located inside the cavity of the plate is shown;

FIG. 8B is a quarter of the illustration of FIG. 8A of the bundle that is located inside the plate, for use as a thermal model for performing thermal analysis.

FIG. 8C is a thermal model used for a qualitative simulation of the temperature distribution, performed by a finite element software, wherein the highest temperature is at the central point of contact between the fibers and the hot plate;

FIG. 9 shows an illustration of a finite elements model of the overlap area of hot and cold fibers. This figure illustrates the heat transfer from the hot fibers to the cold fibers; and

FIG. 10 is a graph of the temperatures (in ° C.) of the hot and cold fibers, taken from the illustration of FIG. 9 that shows a finite elements model of the overlap area of hot and cold fibers.

### DETAILED DESCRIPTION OF THE INVENTION

The present invention provides a thermal contact apparatus that allows efficient heat transfer between different parts, without a solely rigid mechanical interface between them.

The apparatus comprises two plates, each are connected to fibers suitable for heat transfer. One plate is suitable to be attached to a heat-generating device, wherein the external surface of said plate is in contact with the heat-generating device, or the external surface or cover of the heat-generating device, thus absorbing the heat and allowing heat transfer to take place toward the fibers, which are embedded into, or otherwise attached to, said plate by its internal surface. A second similar structure of plate and fibers is provided, and in order to produce heat elimination, the fibers of both structures are interweaved so that heat can be transferred from the fibers that are closer to the heat-generating device to the fibers of the second structure. The heat absorbed in the fibers of the second structure is then transferred to the second plate.

Along the description the plate and fibers of the first structure, which are connected to a heat-generating device, can also be referred to as “hot plate” and “hot fibers”. The plate and fibers of the second structure, which is further away from the heat-generating device, can also be referred to as “cold plate” and “cold fibers”. It should be noted that it does not mean to reflect on the actual temperatures of said parts, but only to indicate which parts are absorbing heat from an external body and transferring it to other parts of the thermal contact apparatus (“hot plate/fibers”), and which parts are absorbing heat from the “hot fibers” and transferring it out of the thermal contact apparatus (“cold plate/fibers”). The reference “first plate/fiber” refers to the “hot plate/fibers”, and the “second plate/fiber” refers to the “cold plate/fibers”. Each plate and corresponding fibers together can also be referred to as “structure”. All said references are for the sake of brevity and does not mean to limit the invention in any way.

It should also be noted that the external heat-generating device can be replaced with other heat sources or components that do not necessarily generate heat themselves, but only require heat elimination therefrom. The plates, according to the present invention, can be replaced with any other parts of different shapes and sizes, suitable to be attached to the fibers and transfer heat. The “plates” along the description refer only to an exemplary embodiment of the invention, since plates are commonly used in heat elimination devices due to geometric convenience, but it should be understood that the plates can be replaced with elements of any other different shapes, and the first plate can be designed in order to be suitable for attachment with any heat-generating device.

Although the phrase “fiber” refers to a threadlike structure, the fibers, according to the present invention, can be replaced with other forms of structures that can be integrated with one another and transfer heat, and the phrase “fiber” is used only for the sake of brevity and does not mean to limit the invention in any way. An example of another form of “fiber” is thin stripes, which can also be easily interweaved with other thin stripes, or an array of pins. In addition, the “fibers” of each plate do not have to be similar, but only to be able to interweave. Furthermore, according to some embodiment of the invention, a plate can comprise more than a single type of fibers.

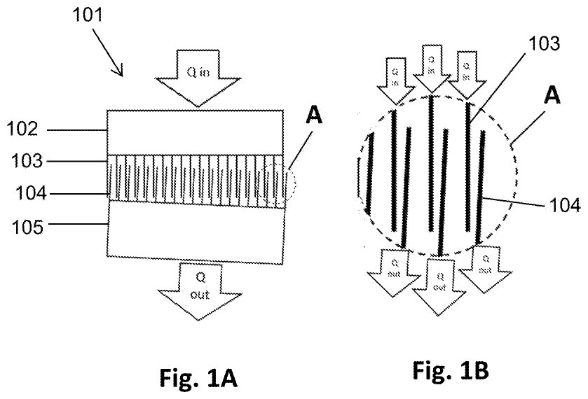

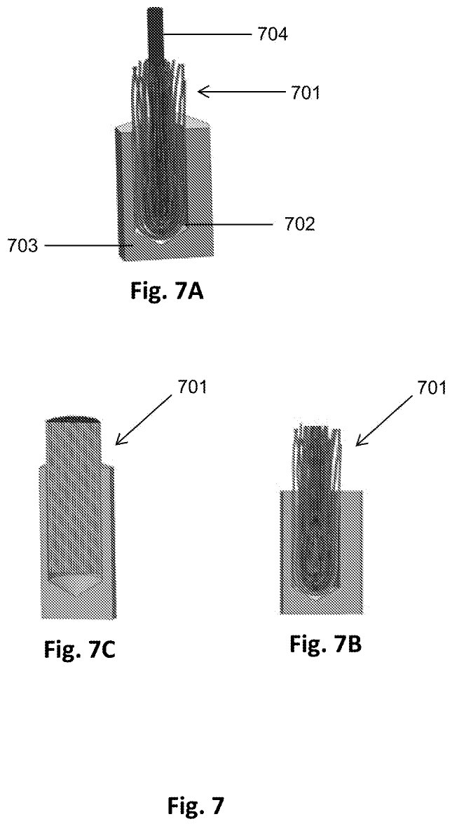

FIG. 1A is a front view of thermal contact apparatus 101, according to one embodiment of the present invention. The hot plate 102 is suitable to be connected to a heat-generating device, and it is also connected to hot fibers 103, which are embedded inside cavities (not shown in this figure, but will be presented with reference to other embodiments of the invention) of plate 102 during the manufacturing process (as will be described in detail with reference to FIG. 7). Cold fibers 104 are embedded into cold plate 105 in the same manner. The two groups of fibers 103 and 104 are interweaved with one another, so that heat, which is generated above plate 102 and marked by Qin, can be transferred from plate 102 to fibers 103, then from fibers 103 to fibers 104, and then from fibers 104 to plate 105. Plate 105 emits the heat to the environment, and said heat is marked by Qout, and can also be assisted by convection.

FIG. 1B is an enlarged view of section A of FIG. 1A, showing fibers 103 and 104 interweaved with one another, and the heat transference through them. Qin marks the heat that warms fibers 103 through plate 102 of FIG. 1A, then heat transference occurs between fibers 103 and 104, and heat is transferred from fibers 104 to the environment as Qout, through plate 105.

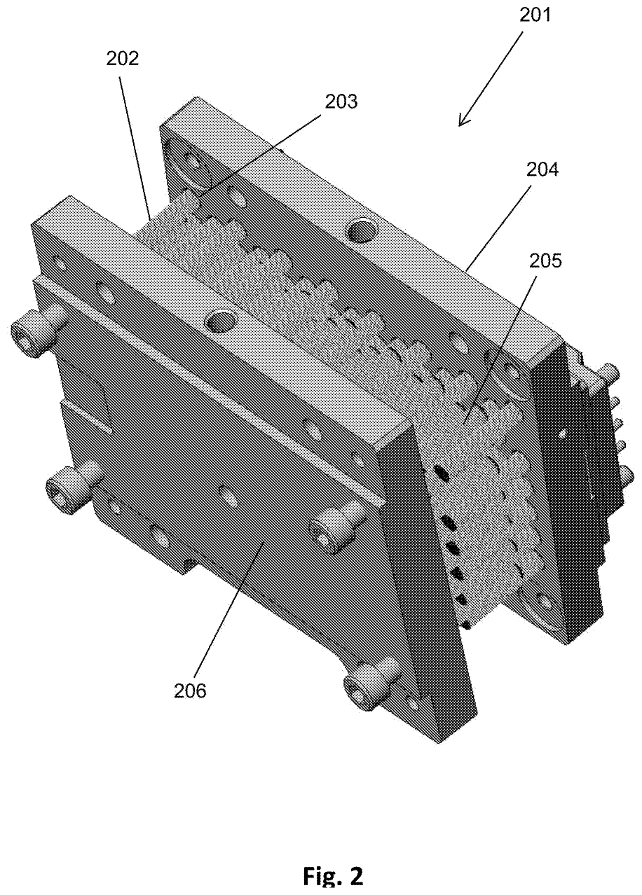

FIG. 2 is a perspective view of an apparatus 201, according to another embodiment of the present invention. FIG. 2 shows that the hot fiber-bundle 202, is located inside a cavity 203, in hot plate 204. Although it is not shown in this figure, cold fiber-bundles, such as bundle 205, are located inside similar cavities in cold plate 206. Each cavity comprises a bundle of fibers, and the hot and cold fibers are interweaved with one another in order to minimize thermal resistance between them. The fibers, according to the present invention, can be connected to the plates as single fibers, as shown in FIGS. 1A-B, or they can be replaced with a bundle of fibers, as shown in FIG. 2.

The array of fibers of each plate can be configured in countless forms, and the positioning of fibers and/or fiber-bundles can be uniform or uneven along the plates. The determination of the fibers and/or fiber-bundles positioning inflicts on the heat transfer between them, and can be easily decided by a person skilled in the art according to the needs of heat elimination in any specific case. According to another embodiment of the invention, the fibers and/or fiber-bundles are detachable from the plates, and can also be reconnected to said plates in order to allow flexibility in the use of said fibers for heat elimination. Such apparatus provides the ability to adjust the thermal contact apparatus according to the temperature of the body it is attached to, to the operational conditions, and to the conditions of the environment.

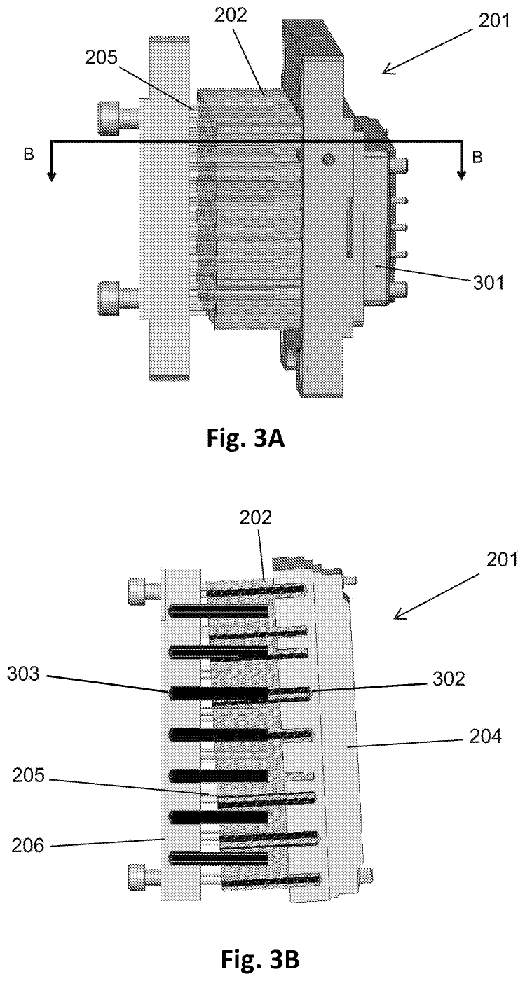

FIG. 3A is a perspective side view of apparatus 201 of FIG. 2, which shows that hot fibers 202 and cold fibers 205 are integrated with one another. In order to enable said integration, the spaces between the fibers of each fiber-bundle are suitable allow the insertion of fibers of the other structure into said spaces. FIG. 3A also shows that apparatus 201 is connected to a heat-generating device 301. Device 301 can be, for example, an electronic component.

When referring to fiber-bundles 202 and 205, the numerals represent each fiber-bundle of the same type (hot/cold), so although the fiber-bundles chosen in each figure are not the same actual bundles, they are equivalent to other bundles of the same type and therefore chosen without distinction.

FIG. 3B is a sectional view of section B-B of FIG. 3A. In this figure it is clearly shown that fibers-bundles 202 and 205 are embedded inside cavities, such as cavities 302 and 303. FIG. 3B also shows the integration of bundles 202 and 205, which allows significant contact between bundles 202 and 205 and therefore enables effective heat transfer from hot plate 204 to cold plate 206, which ultimately provides effective heat elimination of heat generated by device 301 of FIG. 3A (not shown in FIG. 3B) to the environment.

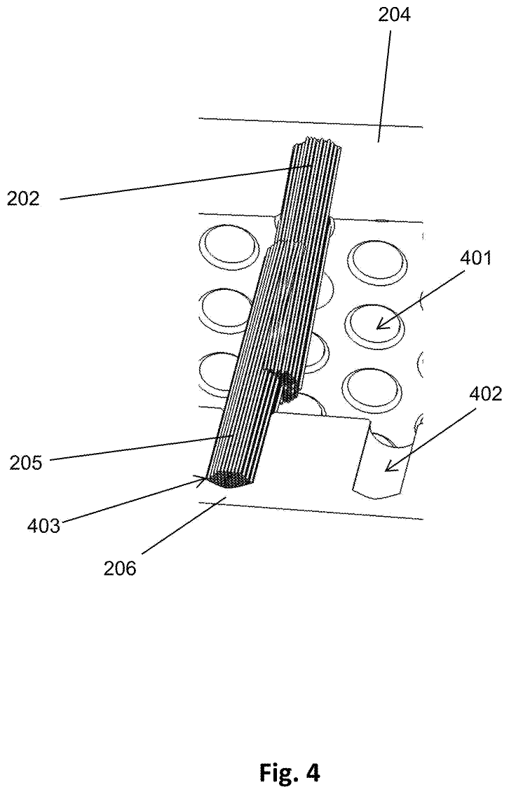

FIG. 4 is a cross-sectional view of the apparatus of FIG. 2, wherein the section was performed parallel to the length of the bundles, and wherein all bundles, except from bundles 202 and 205, were removed in order to comfortably illustrate the cavities of the apparatus and the integration between the two remaining bundles 202 and 205, which are exemplary bundles suitable to be used in the apparatus, according to the present invention. FIG. 4 shows that the fibers of bundles 202 and 205 are interweaved with one another, and such contact between them enables efficient heat transfer. FIG. 4 also shows cavities in plates 204 and 206. Cavity 401 for example, is one of many cavities provided in plate 204 that are suitable to host bundles, such as bundle 202, and cavity 401 is one of many cavities provided in plate 206 that are suitable to host bundles, such as bundle 205. The sectional view of this figure also shows the depth of cavity 402, and cavity 403 while hosting bundle 205.

In addition to the efficient heat transfer provided by such configuration, the use of relatively thin fibers provides a level of flexibility to the apparatus, which is highly important wherein the apparatus is attached to components that inflict movement or vibrations on the heat sink apparatus. A variety of materials can be used for producing the fibers, in order to endure the range of temperatures and/or the movements/shocks/vibrations. One example given along the description is copper fibers, since cooper is highly suitable due to its high heat conduction coefficient value, hardness level, cost etc. Although it is one option for the material of the fibers, it does not mean to limit the invention to copper fibers or to any other metallic or non-metallic materials, and many other materials can serve as alternatives for functioning fibers. Other examples are given along the description with reference to aluminum plates, but it should be noted that the plates are not limited as well to any specific material.

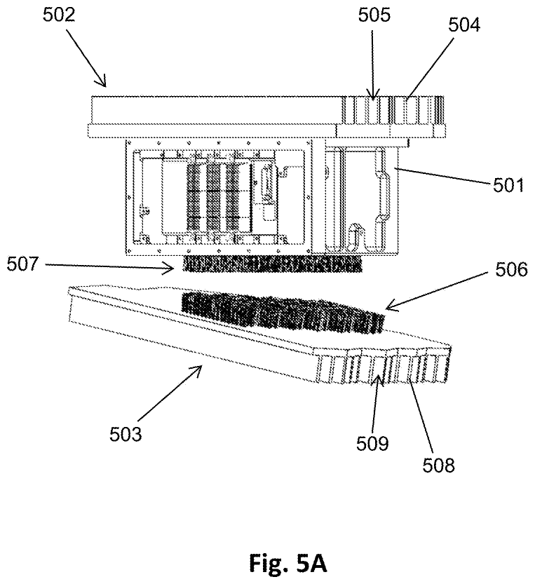

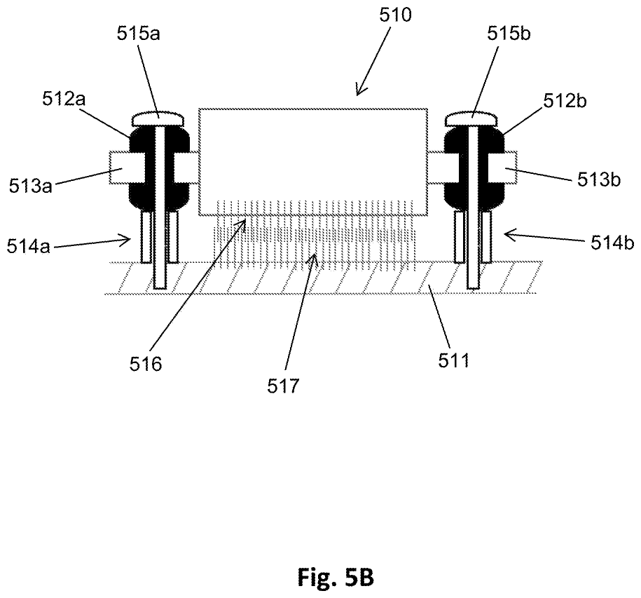

FIG. 5A shows another exemplary illustration of a possible use of the thermal contact apparatus, according to another embodiment of the invention. This figure shows an electronics case 501, a cover 502, and a plate 503. The heat, according to this embodiment, is generated inside case 501. Cover 502 is provided with a heat sink that comprises fins, such as fin 504, and ducts, such as duct 505. Provided with suitable surrounding conditions, cooling air is flowing around cover 502 and through its ducts, thus transferring heat out of cover 502. Case 501 is firmly connected to cover 502, for example, by means of bolts. Although it is not shown in this figure, plate 503 is firmly connected to cover 502.

In FIG. 5A, plate 503 hosts cold fiber-bundles 506, and they are not yet attached to the upper structure of case 501, cover 502, and hot fiber-bundles 507, which are attached to case 501. According to this embodiment, the lower surface of case 501 functions as a “hot plate”, without a plate between them. In some of the cases it is possible to transfer heat directly from the heat-generating element or its casing, as in the example of FIG. 5A. In such cases the first plate is an integral part of a heat-generating device. When plate 503 tighten to cover 502, fiber-bundles 506 and 507 intersect. Plate 503 is also designed as a heat sink provided with fins, such as fin 508, and ducts, such as duct 509.

FIG. 5B shows another exemplary illustration of a possible use of a thermal contact apparatus. In this figure, Inertial Navigation System (INS) 510, which is usually an element with a high dynamic sensitivity, is connected to a plate 511 via shock absorbers 512a-b. INS 510 is connected to axes 513a-b on both its sides, and axes 513a-b pass through shock absorbers 512a-b that are essentially thermally isolated and made of rubber material, which allows INS 510 to move relatively freely. The material of shock absorbers 512a-b can be replaced with any other material that allows the movement of INS 510. Shock absorbers 51a-b are positioned on top of bases 514a-b, which are attached to plate 511, by poles 515a-b that are inserted into plate 511. In order to effectively remove heat from INS 510, it is provided with hot fiber-bundles 516, which are attached to the bottom surface of INS 510 and intersect with cold fiber-bundles 517, which are attached to plate 511. According to this embodiment, INS 510 is able to move, relatively freely, thus preventing damage that can be inflicted on different components of INS 510 and/or the thermal contact apparatus due to movements and/or vibrations, if a freedom of movement was not provided.

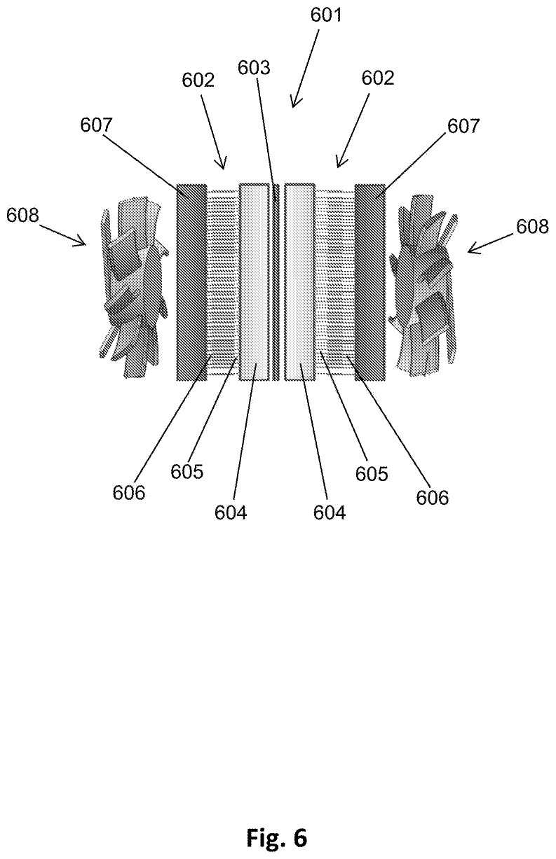

An Experiment which was Performed in Order to Test an Embodiment of the Thermal Contact Apparatus:
In order to test the apparatus and method of the present invention and the heat transfer via a thermal connection performed by fibers, an array was constructed that includes a heated plate and a cooled plate connected to each other by fibers that where attached to each plate and interweaved—cold fibers with hot fibers.
The plates were made of aluminum and the fibers were made of copper. Those materials are suitable and compatible due to their qualities, for example, their temperature range and thermal expansion (which are not the same but their integration provides efficient performance), but as aforesaid, it is only a specific example of the invention for the purpose of illustration, and also for the proof of concept, and does not mean to limit any part of the invention to any specific material or types of materials. The embodiment presented in the following experiment also does not mean to limit the invention to any shape of plates and/or fibers, overlap area, length of fibers, or way of connecting the fibers to the plates.
The diameter of the fibers in the experiment was 0.15 mm.
As illustrated in FIG. 6, the experiment included a serial structure installation, which is a double-sided apparatus 601, wherein a thermal contact structure 602 was provided on each side of a heating sticker 603. The structure comprises: heating sticker 603 in the middle of double-sided apparatus 601, and then on each side of apparatus 601 comprises—a hot plate 604, which was heated by heating sticker 603, hot fibers 605, cold fibers 606, and a cold plate 607, which was cooled by ventilators 608.
The temperatures of the hot plate and the cold plate were measured by thermocouples.
The power was calculated by doubling the sticker resistance with squared current: Q=I²*R.
The thermal resistance was calculated by dividing the temperature difference by half the power.
In order to reduce heat loses to the environment not through the elements of the structure, the device was symmetrically built and was isolated from the environment by using sponges (not shown in the figure) around it, apart from the external surfaces of cold plates 607.

The degree of desired overlap between the fibers was determined by using sets of four thermally insulating plastic spacers of three different lengths, which provided a different size of overlap length between the fibers (small, medium and large overlaps). The spacers (not shown in the figures) in this specific experiment were tube-shaped spacers and were positioned between the two plates, close to their corners. The length of said spacer determines the distance between the two plates, thus determines the length of overlap between two groups (hot and cold) of fibers. An exemplary spacer, according to one embodiment of the invention, is a nylon-made tube-shaped spacer.

The results of the experiment:

Phrases and Definitions:
R— thermal resistance:
Units: [° C./W].
Definition: A heat property and a measurement of a temperature difference by which an object or a material resists a heat flow. Thermal resistance is the reciprocal of thermal conductivity.
The temperature difference was measured between the surfaces of the two plates.
h_eq—equivalent coefficient of contact:
Units: [W/m²K].
Definition: thermal conductivity that is normalized to the area.

Table 1 Below Shows the Experiment Results:

TABLE 1
calculation of equivalent coefficient of contact

| Fibers overlap length | R | h_eq |
|---|---|---|
| [mm] | [° C./W] | [W/m²K] |
| 8.7 | 0.98 | 290 |
| 12.7 | 0.8 | 350 |
| 16.7 | 0.58 | 490 |

In this experiment, as illustrated In FIG. 6, apparatus 601 was designed to transfer heat from a hot body, in this case heating sticker 603, to a cold body, in this case cold plates 607 that were cooled by ventilators 608, with relatively soft mechanical constraints.

A laboratory system has been installed to characterize the performance of the thermal contact apparatus, comprising thermocouples on each plate and on each group of fibers. A maximum contact coefficient of 490/m²K was obtained between the hot and cold components tested in the experiment. This value allows good heat elimination with reasonable resistance to electronic devices, but of course the apparatus according to the present invention is not restricted solely to electronic devices.

According to one embodiment of the invention, the thermal contact apparatus comprises an intermediate material between the fibers, for example, a thermal grease. Such material was not provided in the described experiment and can possibly increase the heat transfer, thus improve the performance of the apparatus of the present invention.

Connection of the Fibers to the Plates:

According to one embodiment of the present invention, In the manufacturing process of the thermal contact apparatus the fiber-bundles are embedded into cavities that are located in the hot and cold plates by a pin that presses them into said cavities. FIG. 7A is a cross-sectional view, wherein the section was performed in parallel to the length of the fibers, in order to show that fiber-bundle 701 is positioned inside cavity 702 of plate 703, and during the manufacturing process pin 704 pushes the fibers of bundle 701 into cavity 702. FIG. 7B shows bundle 701 inside cavity 702 after the manufacturing process and after pin 704 of FIG. 7A was removed. FIG. 7C shows bundle 701 in the same sectional view as in FIGS. 7A and 7B, after the fibers of bundle 701 are aligned.

The bundles, such as bundle 701, remain in the cavities due to the suitability of the shape and size of the bundles to the diameter and mechanical tolerance of the cavities. The fiber embedding process (wherein the fibers are embedded into the cavities), according to FIGS. 7A-C, is a ‘dry’ process—without the use of glue or any other material, and therefore air spaces are created between the fibers inside the cavities of the plates. These spacings increase the total contact resistance of the apparatus. According to another embodiment of the invention, the manufacturing process includes applying a filling material during the fiber embedding process, suitable to change the value of the contact coefficient, which can improve the heat transfer once reduced. An example for a suitable filling material is a type of glue that has a relatively good thermal conductivity.

Heat transfer can be less sufficient as a result of some environmental conditions, for example, at high locations where the air is thin. A significant advantage of the invention is the fact that due to multiple contact points between the fibers, the apparatus is less sensitive to air density, in relation to other heat-transfer devices, and is suitable to essentially overcame this factor, which is known for disrupting the efficiency of heat transfer. The use of a filling material can also be very useful in such cases.

The heat transfer from/to the fibers takes place: between the fibers and the surfaces of the cavities—there is a contact between the fibers and the surface of the cavities, but there are also air spaces and/or a filling material; between the hot and cold fibers in the overlap area of the hot and cold fibers; between the fibers in general, where there are air spaces and/or an intermediate material; and heat conduction within the fibers themselves. The phrases “filling material” and “intermediate material” also include a combination of different materials, and not only a single material or a single type of materials, and the filling of both materials can be full or partial.

Thermal Illustrations:

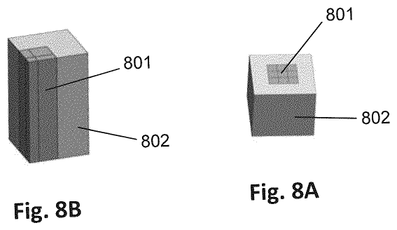

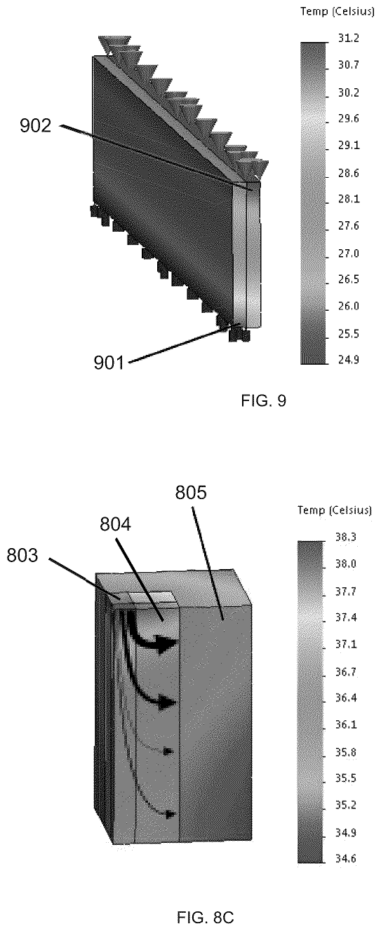

FIG. 8A shows an illustration of a square-shaped bundle 801 inside plate 802, wherein only the part of bundle 801 that is located inside the cavity of plate 802 is shown. FIG. 8B is a quarter of the illustration of FIG. 8A of bundle 801 inside plate 802. FIG. 8C is a thermal model used for a qualitative simulation of the temperature distribution, performed by a finite element software, wherein the highest temperature is at the central point of contact 803 between the fibers 804 and the hot plate 805. The temperature bar on the right represents the temperature values in ° C. with their corresponding colors.

FIG. 9 shows an illustration of a finite elements model of the overlap area of hot and cold fibers. The hottest point 901 is at the first contact point between the hot plate and the hot fibers, and the coldest point 902 is at the first contact point between the cold plate and the cold fibers. The temperature bar on the right represents the temperature values in ° C. with their corresponding colors.

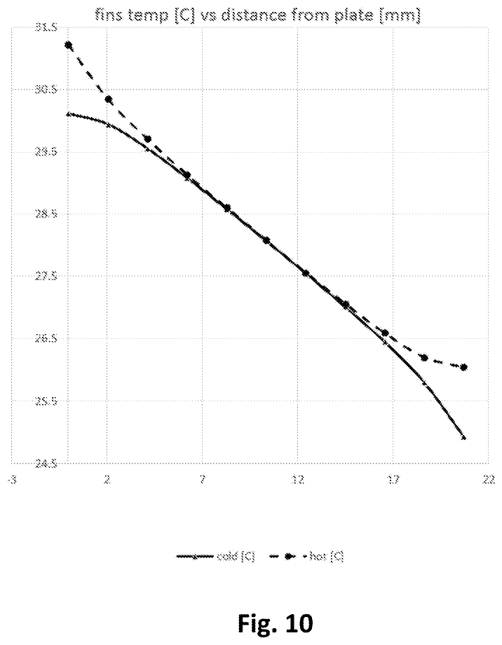

FIG. 10 is a graph of the temperatures (in ° C.) of the hot and cold fibers, taken from the illustration of FIG. 9 that shows a finite elements model of the overlap area of hot and cold fibers, wherein the dashed line is the temperature graph of the hot fibers, and the continuous line is a temperature graph of the cold fibers.

Although FIGS. 8C, 9 and 10 show experimental results, it should be noted that they represent only a single and a very specific experiment, which is not representative as to the heat transfer abilities of the thermal contact apparatus of the present invention. The invention is not limited to a specific range of temperatures, and the temperature distribution may vary according to many factors, such as the materials of the apparatus, the geometry of the apparatus, the heat-generating device, etc.

The thermal contact apparatus, according to the present invention, has several significant advantages. The apparatus enables efficient heat transfer between surfaces, which is suitable to provide a sufficient heat elimination from heat-generating components or from any hot body. The apparatus can be designed with high accuracy to specific needs of different components (such as systems/devices/elements etc.) that require heat elimination, for example, by adjusting the distance between the hot and cold plates and the overlap area of hot and cold fibers. It should also be noted that the length of said fibers can be determine with respect to the needs of different components that require heat elimination.

According to the present invention other parameters can be specifically designed and/or modified for heat elimination control, such as using a filling material in some/all of the spaces between the fibers and the plates, and/or using an intermediate material between some/all of the fibers, which can modify the thermal resistance of the apparatus. In addition, the apparatus and method, according to the present invention, provide a highly resistant mechanical interface that has a loose mechanical connection in the middle—the fibers interface provides certain flexibility, thus providing an apparatus that can endure movements and/or vibrations, even in high frequency and over a relatively extended period of time. The apparatus is suitable to provide an efficient heat elimination for many types of components, for example, it is highly suitable for electronic devices. The apparatus is relatively cost efficient, simple to manufacture, and has a relatively low weight.

Although embodiments of the invention have been described by way of illustration, it will be understood that the invention may be carried out with many variations, modifications, and adaptations, without exceeding the scope of the claims.

1. A thermal contact apparatus, comprising:
a) a first plate, suitable to be connected to a heat source, absorb heat from said heat source, and transfer the heat to other components of the apparatus;
b) a first set of fibers, suitable to absorb heat from said first plate and transfer the heat to other components of the apparatus, wherein said first set of fibers is connected to said first plate;
c) a second set of fibers, suitable to absorb heat from said first set of fibers and transfer the heat to other components of the apparatus, wherein said first and second sets of fibers are in contact; and
d) a second plate, suitable to absorb heat from said second set of fibers and transfer the heat out of the apparatus, wherein said second set of fibers is connected to said second plate;
wherein the first and/or second set of fibers comprise fiber-bundles;
wherein the first set of fibers and the second set of fibers are suitable to interweave with one another; and
wherein the bundled interwoven fibers are adapted to provide a flexible mechanical connection between said first and said second plates.

2. A thermal contact apparatus according to claim 1, wherein the first and/or second plate comprise cavities.

3. A thermal contact apparatus according to claim 1, wherein the first and/or second plate further comprises cavities, and wherein the first and/or second sets of fibers are connected to corresponding plates by the insertion of said sets of fibers into said cavities.

4. A thermal contact according to claim 1, wherein the first plate is an integral part of the heat source.

5. A thermal contact according to claim 1, wherein the first plate is an integral part of the casing of the heat source.

6. A thermal contact according to claim 1, wherein the first and/or second plate further comprises a heatsink structure.

7. A thermal contact apparatus according to claim 1, wherein the first and/or second plate is made of aluminum.

8. A thermal contact apparatus according to claim 1, wherein the first and/or second set of fibers is made of copper.

9. A thermal contact apparatus according to claim 1, wherein the heat source is a heat-generating device.

10. A thermal contact apparatus according to claim 3, further comprising a filling material inside the cavities.

11. A thermal contact apparatus according to claim 1, further comprising an intermediate material suitable to be positioned between the fibers.

12. A method for heat elimination from a heat source, comprising:
a) attaching a first plate to a first set of fibers, wherein said first set of fibers is suitable to absorb heat from said first plate and transfer the heat to other components;
b) attaching said heat source to said first plate, wherein said first plate is suitable to absorb heat from said heat source and transfer the heat to other components;
c) attaching a second set of fibers to a second plate, wherein said second plate is suitable to absorb heat from said second set of fibers and transfer the heat to the environment; and
d) positioning said first set of fibers in relation to a second set of fibers so that said first and second sets of fibers are in contact, thus allowing said second set of fibers to absorb heat from said first set of fibers and transfer the heat to other components;
wherein the first and/or second set of fibers comprise fiber-bundles;
wherein the first set of fibers and the second set of fibers are suitable to interweave with one another; and
wherein the bundled interwoven fibers are adapted to provide a flexible mechanical connection between said first and said second plates.

13. A method for heat elimination according to claim 12, further comprising creating cavities in first and/or second plates.

14. A method for heat elimination according to claim 13, further comprising inserting first and/or second sets of fibers into the cavities of corresponding plates.

15. A method for heat elimination according to claim 13, further comprising filling the cavities with a filling material.

16. A method for heat elimination according to claim 12, further comprising providing an intermediate material suitable to be located between fibers.
